(19) United States
(12) Patent Application Publication
(10) Pub. No.: US 2014/0190563 A1
(43) Pub. Date: Jul. 10, 2014

(54) SOLAR CELL AND METHOD FOR MANUFACTURING SOLAR CELL

(71) Applicant: SANYO Electric Co., Ltd., Osaka (JP)

(72) Inventor: Nozomu TOKUOKA, Osaka (JP)

(73) Assignee: SANYO Electric Co., Ltd., Osaka (JP)

(21) Appl. No.: 14/204,379

(22) Filed: Mar. 11, 2014

Related U.S. Application Data
(63) Continuation of application No. PCT/JP2011/072159, filed on Sep. 28, 2011.

(51) Int. Cl. H01L 31/0224

(52) U.S. Cl. CPC H01L 31/022425
USPC 136/256; 438/98

(57) ABSTRACT

A solar cell is provided with: a photoelectric conversion unit; terminal sections for plating, which are formed on the light receiving surface of the photoelectric conversion unit; and a plated electrode formed on the light receiving surface by means of electrolytic plating using the terminal sections for plating. The terminal sections for plating are formed at positions separated from wiring material connecting sections of the plated electrode, said positions being on the light receiving surface. The plated electrode includes, for instance, a plurality of finger sections, and bus bar sections, each of which is formed to intersect the finger sections, and includes each of the wiring material connecting sections.

### CROSS-REFERENCE TO RELATED APPLICATION

The present application is a continuation under 35 U.S.C. §120 of PCT/JP2011/072159, filed Sep. 28, 2011, which is incorporated herein by reference.

### TECHNICAL FIELD

The present invention relates to a solar cell and a method for manufacturing the solar cell.

### BACKGROUND ART

A solar cell includes a photoelectric conversion portion and an electrode formed on a primary surface of the photoelectric conversion portion. A known method for forming the electrode includes an electrolytic plating method (refer to Patent Literature 1). Patent Literature 1 discloses a solar cell in which a front-surface electrode terminal, to which electrodes of a power-supply device are connected, is coupled to a common electrode collecting carriers from a branch-shaped electrode.

### CITATION LIST

### Patent Literature

Patent Literature 1: Japanese Patent Laid-Open Publication No. 2002-217430

### SUMMARY OF INVENTION

### Technical Problem

When solar cells are modularized, wiring materials electrically connecting a plurality of solar cells are attached to the common electrode. At this time, in the configuration of coupling the front-surface electrode terminal to the common electrode, since the thickness of the common electrode locally varies at the coupling portion with the front-surface electrode terminal, the solar cell may break due to the stress concentrated on the coupling portion at the time of the attachment.

### Solution to Problem

A solar cell according to the present invention includes a photoelectric conversion portion, plating terminal portions provided on a primary surface of the photoelectric conversion portion, and a plated electrode formed on the primary surface by electrolytic plating using the plating terminal portions, wherein the plated electrode includes wiring-material connecting portions to which wiring materials are connected, and the plating terminal portions are provided on the primary surface at positions spaced apart from the wiring-material connecting portions.

A method for manufacturing a solar cell according to the present invention includes an electrode formation step of forming plated electrode on a primary surface of a photoelectric conversion portion by electrolytic plating, wherein, in the electrode formation step, the electrolytic plating is performed, on the primary surface, using positions spaced apart from regions functioning as wiring-material connecting portions of the plated electrode as plating terminal portions.

### Advantageous Effect of Invention

According to the solar cell and the method for manufacturing the same of the present invention, cracks in a solar cell can be prevented.

### BRIEF DESCRIPTION OF DRAWINGS

FIG. 1 is a plan view of a solar cell of a first embodiment in accordance with the present invention, as seen from a light-receiving surface side.

FIG. 2 schematically shows a cross section along arrows A-A in FIG. 1.

FIG. 3 schematically shows a cross section along arrows B-B in FIG. 1.

FIG. 4 is an explanatory drawing of a manufacturing method of the solar cell of the first embodiment in accordance with the present invention.

FIG. 5 is an explanatory drawing of a manufacturing method of the solar cell of the first embodiment in accordance with the present invention.

FIG. 6 shows a modification of the solar cell of the first embodiment in accordance with the present invention.

FIG. 7 shows another modification of the solar cell of the first embodiment in accordance with the present invention.

FIG. 8 is a plan view of a solar cell of a second embodiment in accordance with the present invention as seen from a light-receiving surface side.

FIG. 9 is a plan view of a solar cell of a third embodiment in accordance with the present invention, as seen from a light-receiving surface side.

FIG. 10 is a plan view of a solar cell of a fourth embodiment in accordance with the present invention, as seen from a light-receiving surface side.

FIG. 11 is a magnified view of a D portion of FIG. 10.

FIG. 12 is a plan view of a solar cell of a fifth embodiment in accordance with the present invention, as seen from a light-receiving surface side.

FIG. 13 is a plan view of a solar cell of a sixth embodiment in accordance with the present invention, as seen from a light-receiving surface side.

### DESCRIPTION OF EMBODIMENTS

Embodiments in accordance with the present invention will be described hereinafter in detail with reference to the drawings.

The present invention is not limited to the following embodiments. Moreover, the drawings referred to in the embodiments are schematically illustrated. Proportions of dimensions of objects illustrated in the drawings may be different from proportions of dimensions of actual objects. Specific dimensional proportions and the like of objects should be determined in consideration of the following description.

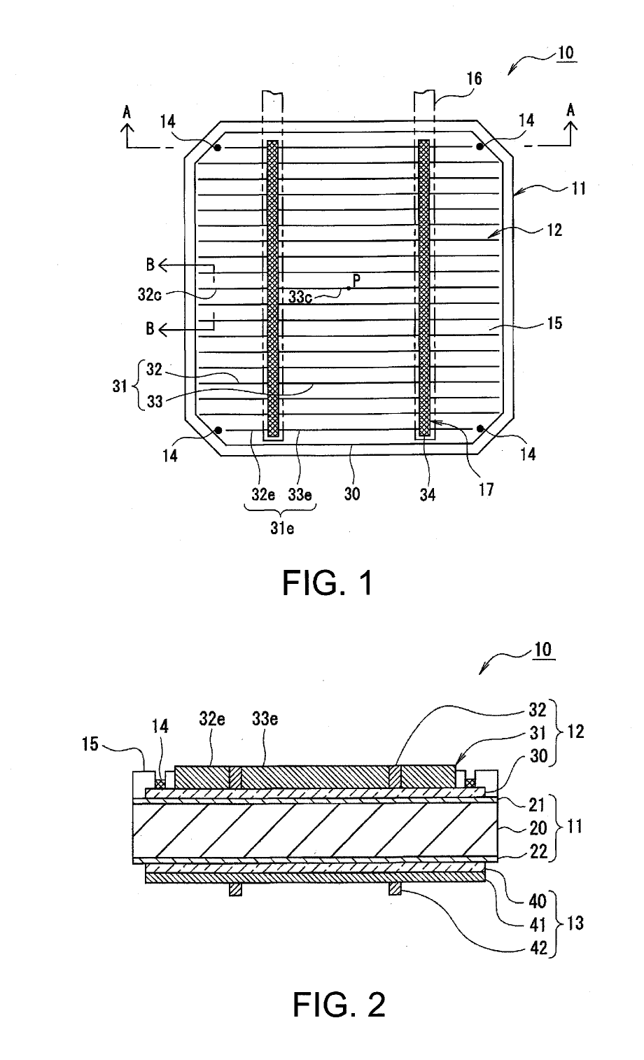

A configuration of a solar cell 10 of a first embodiment is described in detail with reference to FIG. 1 to FIG. 3.

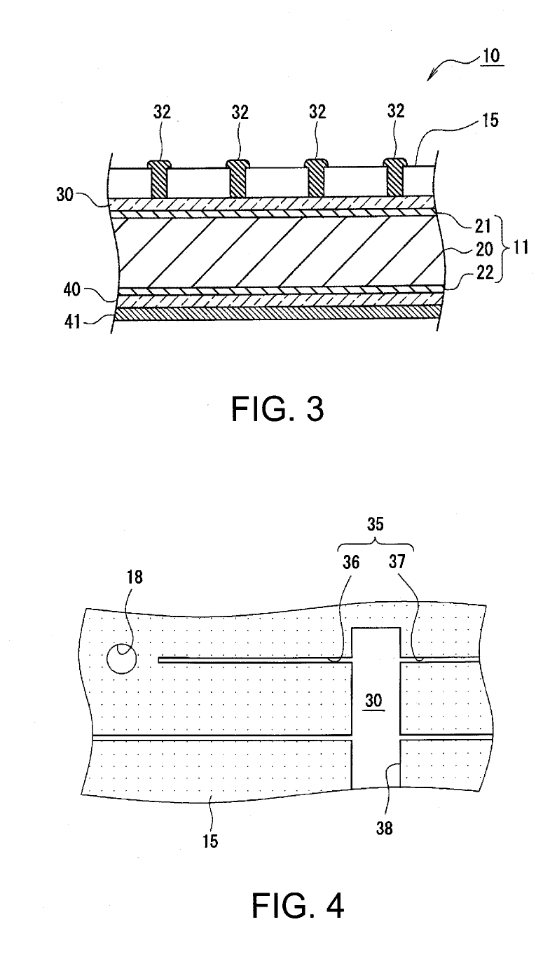

FIG. 1 is a plan view of the solar cell 10 as seen from a light-receiving surface side. FIG. 2 is a cross-sectional view taken along arrows A-A in FIG. 1, showing a cross section by cutting the solar cell 10 in the thickness direction along a longitudinal direction of a finger portion 31. FIG. 3 is a cross-sectional view taken along arrows B-B in FIG. 1, showing a cross section by cutting the solar cell 10 in the thickness direction along a direction orthogonal to the finger portion 31.

The solar cell 10 includes a photoelectric conversion portion 11 that generates carriers (electrons and holes) by receiving sunlight, a light-receiving-surface electrode 12 formed on a light-receiving surface of the photoelectric conversion portion 11, and a rear-surface electrode 13 formed on a rear surface of the photoelectric conversion portion 11. In the solar cell 10, carriers generated by the photoelectric conversion portion 11 are collected by the light-receiving-surface electrode 12 and the rear-surface electrode 13. The solar cell 10 further includes plating terminal portions 14 and a coating layer 15 on the light-receiving surface of the photoelectric conversion portion 11. In this embodiment, a part of the light-receiving-surface electrode 12 is a plated electrode formed by electrolytic plating.

Here, the term “light-receiving surface” means a primary surface on which sunlight is mainly incident from outside of the solar cell 10. For example, more than 50 to 100% of sunlight incident on the solar cell 10 enters from the light-receiving-surface side. Moreover, the term “rear surface” means a primary surface opposite to the light-receiving surface. Side surfaces are defined as surfaces along the thickness direction of the solar cell 10 and perpendicular to the primary surfaces.

The plating terminal portions 14 are portions to which electrodes of a power-supply device (not shown) are connected, in an electrolytic plating step for forming the plated electrode. In other words, the plating terminal portions 14 are said to be connection footmarks of electrode terminals made in the electrolytic plating step. The plating terminal portions 14 usually have a plated layer, and its thickness is thinner than the plated electrode (refer to FIG. 2). Specifically, the thickness is less than or equal to 50% of the thickness of the plated electrode. Although the details are described later, the plating terminal portions 14 have such a characteristic configuration that, for example, they are independently formed from the plated electrode, and their diameters are larger than the width of the finger portions 31, other than the thickness of the plated layer.

The photoelectric conversion portion 11 has, for example, a semiconductor substrate 20, an amorphous semiconductor layer 21 formed on the light-receiving-surface side of the substrate 20, and an amorphous semiconductor layer 22 formed on the rear-surface side of the substrate 20. The amorphous semiconductor layer 21 and the amorphous semiconductor layer 22 are preferably formed so as to cover substantially the entire regions of the light-receiving surface and the rear surface of the substrate 20, respectively. In this specification, the term “substantially the entire region” practically means the entire region of an object, for example, a region of 95 to 100%.

Specific examples of the substrate 20 include an n-type single-crystal silicon substrate. The amorphous semiconductor layer 21 has, for example, a layer structure in which an i-type amorphous silicon layer and a p-type amorphous silicon layer are formed sequentially. The amorphous semiconductor layer 22 has, for example, a layer structure in which an i-type amorphous silicon layer and an n-type amorphous silicon layer are formed sequentially. The photoelectric conversion portion 11 may have a structure in which an i-type amorphous silicon layer and an n-type amorphous silicon layer are sequentially formed on a light-receiving surface of an n-type single-crystal silicon substrate, and an i-type amorphous silicon layer and a p-type amorphous silicon layer are sequentially formed on a rear surface of the n-type single-crystal silicon substrate.

The light-receiving-surface electrode 12 preferably includes a transparent conductive layer 30 formed on the light-receiving surface of the photoelectric conversion portion 11. As the transparent conductive layer 30, transparent conductive oxide (TCO) is applicable in which tin (Sn) or antimony (Sb) or the like is doped into metal oxide such as indium oxide (In₂O₃) and zinc oxide (ZnO). Although the transparent conductive layer 30 may be formed over substantially the entire region on the amorphous semiconductor layer 21, in the configuration shown in FIG. 1, the transparent conductive layer 30 is formed over the entire region except for end edge portions, on the amorphous semiconductor layer 21.

The light-receiving-surface electrode 12 further includes a plurality of (for example fifty) finger portions 31 and a plurality of (for example two) bus-bar portions 34. The finger portions 31 are thin-line shaped electrodes that are extensively formed on the transparent conductive layer 30. The bus-bar portions 34 are electrodes having a larger width and being fewer in number than the finger portions 31, and collect carriers mainly from the finger portions 31. The finger portions 31 and the bus-bar portions 34 are disposed crossing with each other and are electrically connected to each other. The thicknesses of the finger portions 31 and the bus-bar portions 34 are substantially the same, and preferably range, for example, from 30 to 50 μm.

In this embodiment, the two bus-bar portions 34 are disposed parallel to each other at a predetermined interval, and the plurality of finger portions 31 are disposed substantially orthogonal to the bus-bar portions 34. The finger portions 31 have first finger portions 32 extending from each of the bus-bar portions 34 to the end edge sides of the light-receiving surface and second finger portions 33 connecting two bus-bar portions 34, and the two first finger portions 32 and the one second finger portion 33 are disposed side by side along a direction substantially orthogonal to the bus-bar portions 34. In particular, the two first finger portions 32 are disposed so as to extend from the two bus-bar portions 34 to the end portions of the photoelectric conversion portion 11. The one second finger portion 33 is disposed between the two bus-bar portions 34. In this specification, the term “substantially orthogonal” includes a state assumed to be practically orthogonal, for example, a state in which the angle formed between the finger portions 31 and the bus-bar portions 34 is 90°±5°.

Moreover, in this embodiment, the finger portions 31 and the bus-bar portions 34 are referred to as a plated electrode (hereinafter, unless otherwise noted, the term “plated electrode” means the finger portions 31 and the bus-bar portions 34). The plated electrode is formed on the transparent conductive layer 30 by electrolytic plating using the plating terminal portions 14. Although the plated electrode is composed of metal such as nickel (Ni), copper (Cu), or silver (Ag), for example, the plated electrode preferably has a stacked structure of a nickel plated layer and a copper plated layer.

The rear-surface electrode 13 includes a transparent conductive layer 40 formed on the amorphous semiconductor layer 22, a metal layer 41 formed on the transparent conductive layer 40, and a plurality of bus-bar portions 42 formed on the metal layer 41. The metal layer 41 is a thin film composed of a metallic material such as silver (Ag) having high light reflectivity and high conductivity. The bus-bar portions 42 can be formed by using a conductive paste. In the rear-surface electrode 13, the metal layer 41 may be changed to the finger portions, and the finger portions and the bus-bar portions 42 may be formed by electrolytic plating.

The plurality of solar cells 10 are arranged on the same plane, for example, and are modularized by using protective members covering the light-receiving sides and the rear-surface sides, and a filling material provided between the protective members. At this time, wiring materials 16 electrically connecting between the solar cells 10 are attached to the bus-bar portions 34 and 42. The wiring materials 16 are connected to the bus-bar portions 34 of one adjacent solar cell 10, and are connected to the bus-bar portions 42 of the other solar cell 10 by using, for example, conductive adhesive.

The wiring materials 16 are connected onto the bus-bar portions 34. More specifically, the bus-bar portions 34 include wiring-material connecting portions 17 to which the wiring materials 16 are connected. In the configuration shown in FIG. 1, the width of the wiring materials 16 is wider than that of the bus-bar portions 34, and the wiring materials 16 are provided across a part of the finger portions 31. Portions of the plated electrode covered by the wiring materials 16 are the wiring-material connecting portions 17, and in this case, the entire bus-bar portions 34 and the vicinity of the bus-bar portions 34 of the finger portions 31 are the wiring-material connecting portions 17.

The configuration on the transparent conductive layer 30 of the solar cell 10, more specifically, the plating terminal portions 14, the coating layer 15, the finger portions 31, and the bus-bar portions 34 are described in more detail below.

The insulating coating layer 15 is formed on the transparent conductive layer 30. Although the details will be described later, the plating terminal portions 14 and the plated electrode are formed in an opening of the coating layer 15. The coating layer 15 is preferably formed on substantially the entire region except for regions where the plating terminal portions 14 are provided and a region where the plated electrode is formed. In this embodiment, the coating layer 15 is also formed on the end edge portions of the amorphous semiconductor layer 21 (refer to FIG. 2). The thickness of the coating layer 15 ranges, for example, from 20 to 30 μm, and is set to be, for example, slightly thinner than the thickness of the plated electrode (refer to FIG. 3).

The coating layer 15 functions as a mask in an electrolytic plating step described later. Although the material constituting the coating layer 15 is not especially limited if metal plating is not deposited in the electrolytic plating step, the material is preferably a photocurable resin containing, for example, an epoxy resin, from the view point of, for example, productivity and adhesiveness to the filling material.

The plating terminal portions 14 is provided at positions spaced apart from the wiring-material connecting portions 17 of the plated electrode on the transparent conductive layer 30. Here, the term “spaced apart” means that the plating terminal portions 14 and the wiring-material connecting portions 17 are not overlapped. From the view point of suppressing a local increase in thickness of the wiring-material connecting portions 17, the plating terminal portions 14 and the wiring-material connecting portions 17 are preferably apart to some extent. The distance between both portions is preferably more than or equal to 1 mm, is more preferably more than or equal to 2 mm, and is even more preferably more than or equal to 3 mm.

The shape of the plating terminal portions 14, which is not specifically limited, is set to be, for example, a substantially circular shape in a plan view. The size of the plating terminal portions 14 is, for example, about 0.1 to 1.0 mm in diameter, and the diameter is larger than the width of the finger portions 31.

Although the electrolytic plating can be performed even if only one plating terminal portion 14 exists, from the view point of, for example, the evenness of the thickness of the plated electrode and the time reduction in the electrolytic plating step, the plating terminal portions 14 are preferably provided plurally. In the configuration shown in FIG. 1, the four plating terminal portions 14 are provided on the end edge portions of the light-receiving surface with a substantially rectangular shape. More specifically, each of the plating terminal portions 14 is provided at a position where the distance from the center P of the light-receiving surface is substantially the same in the vicinity of each corner portion of the light-receiving surface. Moreover, the distances between the plating terminal portions 14 adjacently located along the end edge portions of the light-receiving surface are both substantially the same. The two plating terminal portions 14 located at the opposite corners of the light-receiving surface are located on the phantom straight line passing through the center P.

The plating terminal portions 14 are preferably provided adjacent to the finger portions 31. In other words, the finger portions 31 are preferably formed up to the vicinity of the plating terminal portions 14 located apart from the wiring-material connecting portions 17. The plating terminal portions 14 and the finger portions 31 are not in contact with each other, and clearances are provided between them. The clearances preferably range from about 0.1 to 3.0 mm, for example.

The plating terminal portions 14 are preferably provided adjacent to the finger portions 31 connected to positions located within a range from longitudinally end portions of the bus-bar portions 34 to substantially one-quarter of the length of the bus-bar portions 34, of the plurality of finger portions 31. The plating terminal portions 14 are provided, for example, at positions adjacent to first finger portions 32e connected to the longitudinally end portions of the bus-bar portions 34. The first finger portions 32e are finger portions disposed at ends of the columns of the first finger portions 32 (in the embodiment, each finger portion disposed at the center of the columns is referred to as “first finger portion 32c”).

The plating terminal portions 14 can be provided on the extended lines of the first finger portions 32e. The plating terminal portions 14 are provided, for example, on the extended lines of the first finger portions 32e by providing clearances between the end portions of the first finger portions 32e located at the opposite side of the bus-bar portions 34 and the coating layer 15.

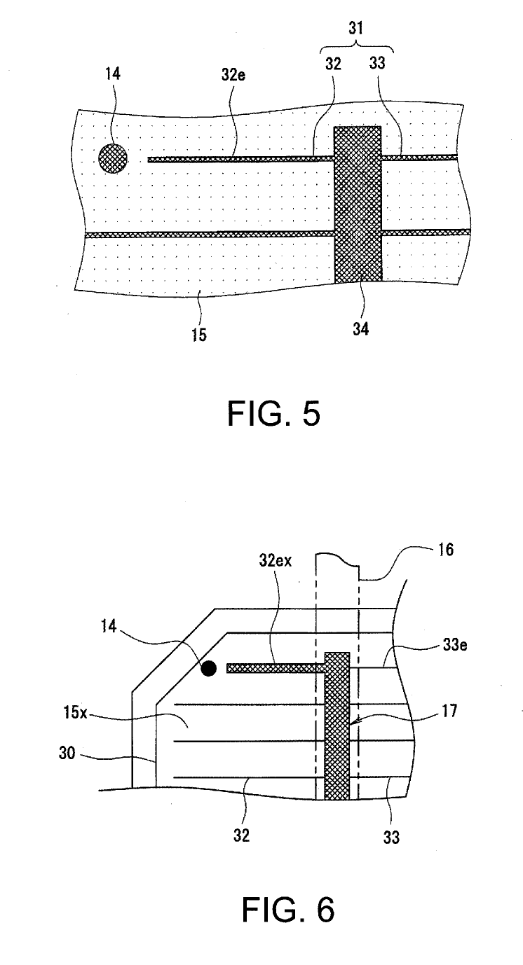

Next, manufacturing steps of the solar cell 10 provided with the above configuration, particularly a formation step of the light-receiving-surface electrode 12, will be described in detail, while referring to FIG. 4 and FIG. 5 as appropriate.

In the following description it is assumed that the plated electrode is formed by nickel plating and copper plating. Although the plating terminal portions 14 exist on the light-receiving surface of the solar cell 10, a step of cutting a part on which the plating terminal portions 14 are provided can be added after the electrolytic plating step.

In the manufacturing steps of the solar cell 10, first, the photoelectric conversion portion 11 is manufactured by a known method (the detailed description about the manufacturing steps of the photoelectric conversion portion 11 is omitted). After the photoelectric conversion portion 11 is prepared, the light-receiving-surface electrode 12 is formed on the light-receiving surface of the photoelectric conversion portion 11, and the rear-surface electrode 13 is formed on the rear surface of the photoelectric conversion portion 11. In this embodiment, the light-receiving-surface electrode 12 is formed after the formation of the rear-surface electrode 13, but the formation order is not particularly limited to this.

In the formation step of the rear-surface electrode 13, the transparent conductive layer 40 is formed on the amorphous semiconductor layer 22, and then the metal layer 41 is formed on the transparent conductive layer 40. The transparent conductive layer 40 and the metal layer 41 can be formed by using, for example, a sputtering method. The transparent conductive layer 40 can be formed to a thickness of about 30 to 200 nm, and the metal layer 41 can be formed to a thickness of about 0.1 to 5 μm.

Subsequently, the bus-bar portions 42 are formed on the metal layer 41. The bus-bar portions 42 can be formed by, for example, burning after a conductive paste is screen-printed on the metal layer 41. The bus-bar portions 42 can be formed to a width of about 0.5 to 3.0 mm and to a thickness of about 10 to 50 μm. The rear-surface electrode 13 may have a structure in which the bus-bar portions 42 are not provided.

The formation step of the light-receiving-surface electrode 12 includes a step of forming the transparent conductive layer 30 on the light-receiving surface of the photoelectric conversion portion 11, a mask formation step of forming a mask on the transparent conductive layer 30, and an electrolytic plating step of forming the plated electrode by the electrolytic plating on the transparent conductive layer 30 on which the mask is formed. The transparent conductive layer 30 is formed over the entire region on the amorphous semiconductor layer 21 except for the end edge portions by, for example, the same method as used for forming the transparent conductive layer 40.

In the mask formation step, the coating layer 15 composed of a photocurable resin is formed on the transparent conductive layer 30 as a mask. In the mask formation step, for example, the coating layer 15 patterned over the entire region on the light-receiving surface is formed. The patterned coating layer 15 can be formed by a known method. For example, after a thin-film layer composed of the photocurable resin is formed on the light-receiving surface by, for example, a spin coat method or a spray coat method, the coating layer 15 patterned by a photolithoprocess is formed. The patterned coating layer 15 may be formed by using a printing method such as screen printing.

The coating layer 15 is patterned so as to have terminal openings 18 that expose the transparent conductive layer 30 in regions for providing the plating terminal portions 14 and electrode openings that expose the transparent conductive layer 30 in a region for forming the plated electrode. The electrode openings include finger openings 35 that expose regions for forming the finger portions 31, and bus-bar openings 38 that expose regions for forming the bus-bar portions 34.

In this embodiment, the two bus-bar openings 38, which are formed parallel at a predetermined distance from each other, and the plurality of finger openings 35, which are substantially orthogonal to the two bus-bar openings 38, are formed. The terminal openings 18 are formed at positions spaced apart from the bus-bar openings 38 and in the vicinity of the finger openings 35. Moreover, the terminal openings 18 are formed on the extended lines of the first finger openings 36 so as to be adjacent to the first finger openings 36 extending from the bus-bar openings 38 to the end edge portions of the light-receiving surface, of the finger openings 35 communicating with longitudinal end portions of the bus-bar openings 38.

In the coating layer 15, the four terminal openings 18 are formed at the end edge portions on the transparent conductive layer 30 and at the vicinity of each corner portion on the transparent conductive layer 30. Each of the terminal openings 18 is formed so as to have substantially the distance from the center P, and to have the same distance between the terminal openings 18 adjacently located along the end edge portions. The two terminal openings 18 located at opposite corners are formed on the phantom straight line passing through the center P.

In this embodiment, although the coating layer 15 is not removed after the electrolytic plating step, the mask may be removed after the electrolytic plating step. In the formation step of the light-receiving-surface electrode 12, on the transparent conductive layer 30, the electrolytic plating is performed using positions spaced apart from a region functioning as wiring-material connecting portions 17 of the plated electrode as the plating terminal portions 14.

In the electrolytic plating step, the electrolytic plating is performed using the photoelectric conversion portion 11 on which the coating layer 15 is formed as a negative electrode and using a nickel plate as a positive electrode. In the photoelectric conversion portion 11, electrodes of a power-supply device are connected to regions on the transparent conductive layer 30 exposed from the terminal openings 18. More specifically, the electrolytic plating is performed using the exposed regions as the plating terminal portions 14. The electrolytic plating is performed by soaking the photoelectric conversion portion 11 and the nickel plate in a plating solution and applying a current between them with the rear surface being insulation-coated (for example, an insulating resin layer covering the rear surface is formed and then the layer is removed after the electrolytic plating step) so that a metal plated layer is not deposited on the rear surface of the photoelectric conversion portion 11. A known nickel plating solution containing nickel sulfate, or nickel chloride can be used as a plating solution.

Thus, a nickel plated layer is formed on the transparent conductive layer 30 exposed from the finger openings 35 and the bus-bar openings 38. Moreover, a thin nickel plated layer is formed at the plating terminal portions 14 to which the electrodes of the power-supply device were connected.

Subsequently, the electrolytic plating is performed using a copper plate as a positive electrode, by using a known copper plating solution containing copper sulfate or copper cyanide. As a result of this, a copper plated layer is formed on the previous formed nickel plated layer, and the finger portions 31 and the bus-bar portions 34 configured by the nickel plated layer and the copper plated layer are formed. The copper plated layer is formed on the nickel plated layer, also at the plating terminal portions 14. The thickness of the metal plated layer can be adjusted by the amount of applied current (current×time).

As described above, the solar cell 10 is manufactured having the plated electrode formed on the light-receiving surface. By performing the electrolytic plating using the coating layer 15 patterned in the mask formation step as a mask, a local increase in the thickness of the wiring-material connecting portions 17 can be suppressed. Thus, the stress occurring during attachment of the wiring materials 16 does not concentrate to a part of the photoelectric conversion portion 11, thereby preventing breaking of the solar cell 10. When the plating terminal portions 14 and the wiring-material connecting portions 17 are overlapped, although the thickness of the wiring-material connecting portions 17 sometimes locally decreases, the local decrease in thickness can be prevented, according to the above manufacturing steps.

Moreover, the plurality of plating terminal portions 14 are provided having excellent symmetry on the end edge portions of the light-receiving surface without being deviated to a part on the light-receiving surface. For this reason, the plated electrode can be quickly formed, and the thickness of the plated electrode tends to be uniform.

Further, by providing clearances between the plating terminal portions 14 and the finger portions 31, peeling of the finger portions 31 can be prevented when the electrodes of the power-supply device are removed from the plating terminal portions 14. In other words, although it is assumed that a part of the metal plated layer of the plating terminal portions 14 sticks to the electrodes and peels off when the electrodes of the power-supply device are removed, the finger portions 31 does not peel off due to the peeling.

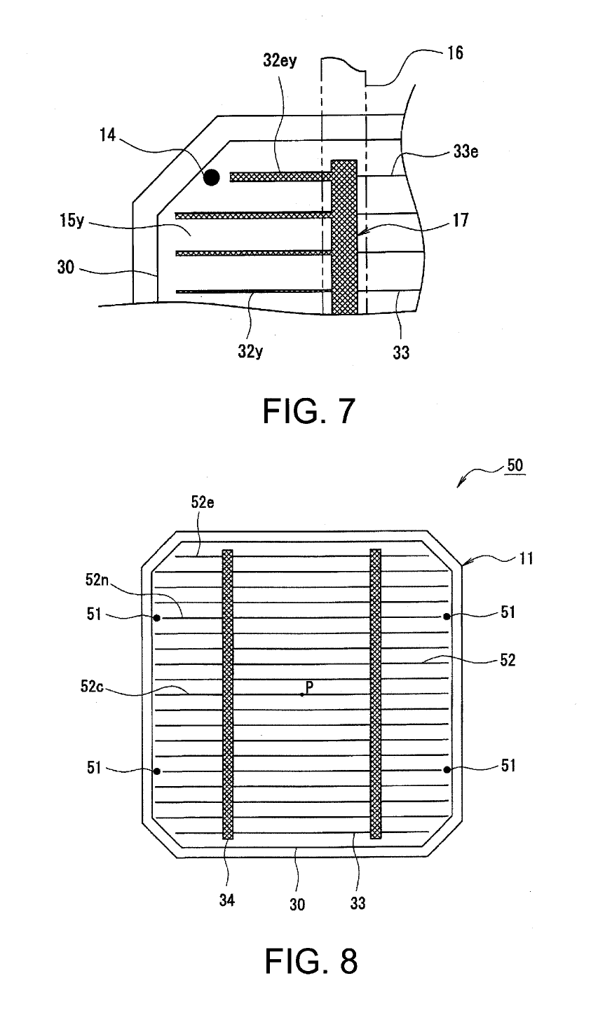

Next, a modification of the solar cell 10 is shown in FIG. 6 and FIG. 7.

In the configuration shown in FIG. 6, the width of first finger portions 32ex closest to the plating terminal portions 14 is larger than the width of the other first finger portions 32 and second finger portions 33 and 33e. Usually, the amount of deposition of metal plating becomes larger in regions near the plating terminal portions 14, but the thickness of the first finger portions 32ex can be reduced by widening the width of the first finger openings. The thickness of the first finger portions 32ex is substantially the same as the thickness of, for example, the other first finger portions 32 and the second finger portions 33 and 33e.

The configuration shown in FIG. 6 can be formed by making the first finger openings corresponding to the first finger portions 32ex wider than the width of the other first finger openings. More specifically, in the mask formation step, a coating layer 15x is formed which is patterned so that the width of the first finger openings closest to the terminal openings is wider than the width of the other first finger openings.

In the configuration shown in FIG. 7, the width of first finger portions 32y formed in the vicinity of the plating terminal portions 14 becomes wider approaching the plating terminal portions 14. In other words, first finger portions 32ey closest to the plating terminal portions 14 have the largest width, and the width of the first finger portions 32y becomes narrower as they move away from the first finger portions 32ey. For example, the width of the first finger portions 32y up to the tenth first fingers or fifth first fingers counted from the plating terminal portions 14 is made wider approaching the plating terminal portions 14. The first finger portions having a large distance from the plating terminal portions 14 (for example, eleventh first finger portions counted from the plating terminal portions 14) can be set to be substantially the same width as the adjacent first finger portions (for example, twelfth first finger portions counted from the plating terminal portions 14).

The configuration shown in FIG. 7 is formed by using a coating layer 15y patterned so that the width of the first finger openings located in the vicinity of the terminal openings becomes larger approaching the terminal openings. On the other hand, in all the first finger portions, the width may be wider approaching the plating terminal portions 14. Moreover, the width of the second finger portions 33 and 33e may be changed according to the distance from the plating terminal portions 14.

According to the configurations shown in FIG. 6 and FIG. 7, the thickness of the plated electrode can easily be made more uniform by changing the width of the electrode openings according to the distance from the plating terminal portions 14. For this reason, the irregularity of the wiring-material connecting portions 17 can be further suppressed.

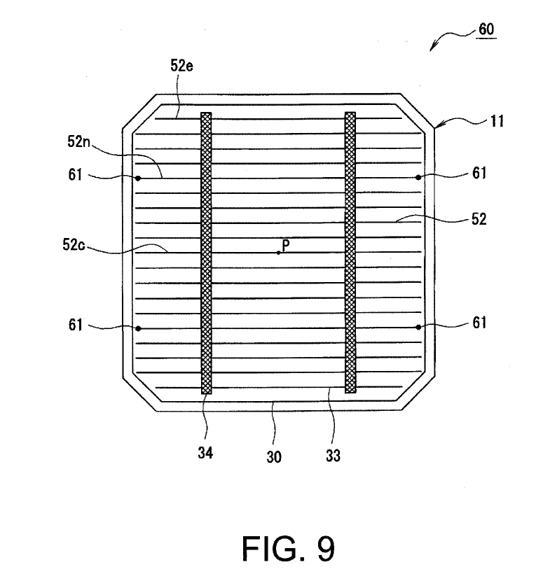

Next, configurations of solar cells 50 to 90 of second to sixth embodiments are described in detail, while referring to FIG. 8 to FIG. 13.

Hereinafter, differences between the first embodiment and embodiments described below are described in detail. In the embodiments described below, the same elements as those of the first embodiment are designated by the same reference numerals without duplicated explanation thereof. Moreover, in the solar cells 50 to 90, finger portions and bus-bar portions of the light-receiving-surface electrode are referred to as a plated electrode formed through the same electrode formation step as the solar cell 10, as in the solar cell 10.

FIG. 8 is a plan view of the solar cell 50 of a second embodiment as seen from a light-receiving surface side.

In the solar cell 50, plating terminal portions 51 are provided in the vicinity of the first finger portions 52n on the extended line of the first finger portions 52n. The first finger portions 52n are disposed between first finger portions 52e at the farthest points of the columns and first finger portions 52c at the center of the columns, of a plurality of first finger portions 52 extending from bus-bar portions 34 to end edge portions of a light-receiving surface. More specifically, the first finger portions 52n are disposed closer to the first finger portions 52e than to the center between the first finger portions 52e and the first finger portions 52c. In other words, the plating terminal portions 51 are provided within a range from ends of the light-receiving surface to substantially one-quarter of the length of one side. As in the plating terminal portions 14, the four plating terminal portions 51 are provided at positions having substantially the same distance from the center P and in which the distances between the plating terminal portions 51 along end edge portions are substantially the same. According to the solar cell 50, for example, the amount of current flowing through the end of the light-receiving surface and the amount of current flowing through the center of the light-receiving surface can be substantially the same, so that the thickness of the plated electrode is easy to make uniform.

FIG. 9 is a plan view of a solar cell 60 of a third embodiment as seen from a light-receiving surface side.

The solar cell 60 has a configuration in which plating terminal portions 61 are provided on first finger portions 52n. In other words, the plating terminal portions 61 constitute parts of the first finger portions 52n. For this reason, carriers collected by metal plating of the plating terminal portions 61 can be recovered through the first finger portions 52n. The solar cell 60 can be manufactured by using, for example, a mask pattern having terminal openings formed overlapping first finger openings corresponding to the first finger portions 52n.

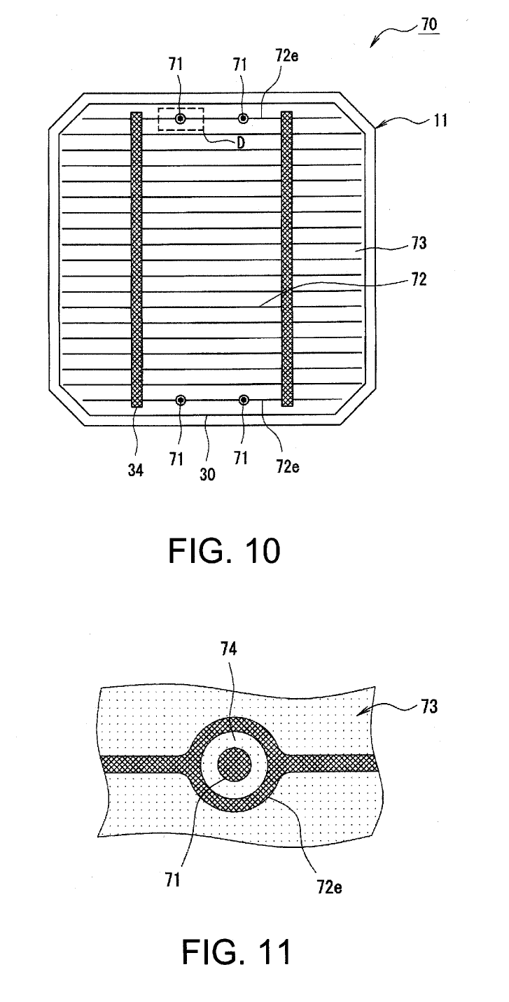

FIG. 10 is a plan view of a solar cell 70 of a fourth embodiment as seen from a light-receiving surface side, and FIG. 11 is a magnified view of a D portion of FIG. 10.

In the solar cell 70, two plating terminal portions 71 are provided on the extended lines as each second finger portion 72e disposed at the farthest point of the column, of a plurality of second finger portions 72 connecting two bus-bar portions 34. The second finger portions 72e are formed so as to surround circular portions 74 that are circular clearances formed around the plating terminal portions 71. Thus, portions between two plating terminal portions 71 of the second finger portions 72 are connected to portions extending from two bus-bar portions 34, and carriers can be recovered from regions between the plating terminal portions 71. This structure can be formed by, for example, patterning a coating layer 73 so that second finger openings corresponding to the second finger portions 72e and terminal openings corresponding to the plating terminal portions 71 are overlapped, and so as to have the circular portions 74 separating the two openings.

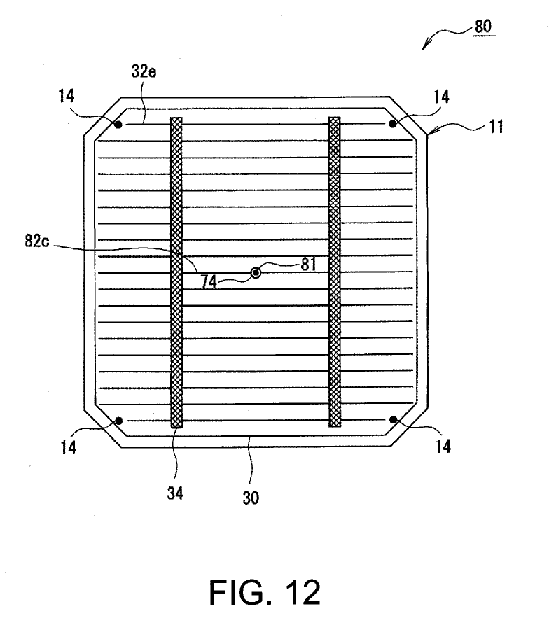

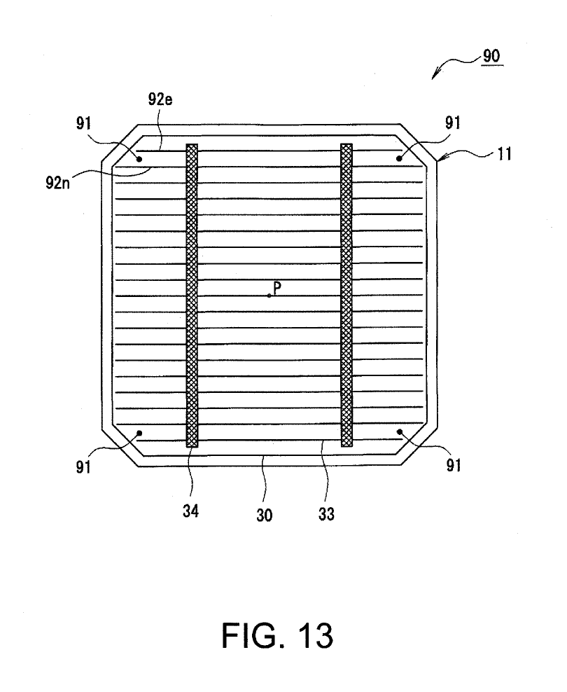

FIG. 12 is a plan view of a solar cell 80 of a fifth embodiment as seen from a light-receiving surface side.

The solar cell 80 has a configuration in which a fifth plating terminal portion 81 is provided at the center P of the light-receiving surface in addition to four plating terminal portions 14 provided in the solar cell 10. The plating terminal portion 81 is provided on the extended straight line as a second finger portion 82c. The second finger portion 82c is formed to surround the periphery of the plating terminal portion 81 through a circular portion 74.

FIG. 13 is a plan view of a solar cell 90 of a sixth embodiment as seen from a light-receiving surface side.

The solar cell 90 has a configuration in which plating terminal portions 91 are provided adjacent to first finger portions 92e, but the plating terminal portions 91 and the first finger portions 92e are not located on the same straight line. The plating terminal portions 91 are provided between the first finger portions 92e and the first finger portions 92n disposed next to the first finger portions 92e.

Each embodiment described above can be modified as appropriate within a scope not departing from the object of the present invention.

For example, each of the embodiments described above may be combined with each other. Specifically, the plating terminal portions 14 of the first embodiment may be formed on the first finger portions 32e as in the second embodiment. Alternatively, in the second embodiment to the sixth embodiment, the width of the finger portions may become wider approaching the plating terminal portions by changing the width of the finger openings according to the distances from the plating terminal portions.

In the above description, although the light-receiving-surface electrode is explained as a configuration including the finger portions and the bus-bar portions, the light-receiving-surface electrode may not include the bus-bar portions. In this case, since the wiring materials are connected to the finger portions, the plating terminal portions are formed spaced apart from the wiring-material connecting portions of the finger portions.

Further, in the above description, the configuration provided with four or more four plating terminal portions is exemplified, but the number of plating terminal portions is not particularly limited, and may be two, for example. In this case, preferably, one plating terminal portion and the other plating terminal portion have substantially the same distance from the center of the light-receiving surface, and they are provided on the phantom straight line passing through the center.

### REFERENCE SIGNS LIST

10: solar cell, 11: photoelectric conversion portion, 12: light-receiving-surface electrode, 13: rear-surface electrode, 14: plating terminal portion, 15: coating layer, 16: wiring material, 17: wiring-material connecting portion, 18: terminal opening, 20: semiconductor substrate, 21 and 22: amorphous semiconductor layer, 30 and 40: transparent conductive layer, 31, 31c, and 31e: finger portion, 32, 32c, and 32e: first finger portion, 33, 33c, and 33e: second finger portion, 34 and 42: bus-bar portion, 35: finger opening, 36: first finger opening, 37: second finger opening, 38: bus-bar opening, 41: metal layer, 74: circular portion, P: center of light-receiving surface.

1. A solar cell comprising:
a photoelectric conversion portion;
plating terminal portions provided on a primary surface of the photoelectric conversion portion; and
a plated electrode formed on the primary surface by electrolytic plating using the plating terminal portions,
wherein the plated electrode includes wiring-material connecting portions to which wiring materials are connected, and
the plating terminal portions are provided spaced apart from the wiring-material connecting portions on the primary surface.

2. The solar cell according to claim 1,
wherein the plating terminal portions include a first plating terminal portion and a second plating terminal portion, and
the first plating terminal portion and the second plating terminal portion have the same distance from a center of the primary surface and are provided on the same straight line passing through the center.

3. The solar cell according to claim 1,
wherein the four or more plating terminal portions are provided at end edge portions of the primary surface, and
each of the plating terminal portions has the same distance from the center of the primary surface, and the distances between the plating terminal portions adjacently located along the end edge portions are the same.

4. The solar cell according to claim 2,
wherein the four or more plating terminal portions are provided at end edge portions of the primary surface, and
each of the plating terminal portions has the same distance from the center of the primary surface, and the distances between the plating terminal portions adjacently located along the end edge portions are the same.

5. The solar cell according to claim 1,
wherein the plated electrode includes a plurality of finger portions and bus-bar portions formed so as to cross the finger portions and including the wiring-material connecting portion, and
the plating terminal portions are provided on the finger portions or at positions in the vicinity of the finger portions.

6. The solar cell according to claim 2,
wherein the plated electrode includes a plurality of finger portions and bus-bar portions formed so as to cross the finger portions and including the wiring-material connecting portion, and
the plating terminal portions are provided on the finger portions or at positions in the vicinity of the finger portions.

7. The solar cell according to claim 3,
wherein the plated electrode includes a plurality of finger portions and bus-bar portions formed so as to cross the finger portions and including the wiring-material connecting portion, and
the plating terminal portions are provided on the finger portions or at positions in the vicinity of the finger portions.

8. The solar cell according to claim 4,
wherein the plated electrode includes a plurality of finger portions and bus-bar portions formed so as to cross the finger portions and including the wiring-material connecting portion, and
the plating terminal portions are provided on the finger portions or at positions in the vicinity of the finger portions.

9. The solar cell according to claim 5,
wherein the plating terminal portions are provided on the finger portions connected to positions within the range from longitudinal end portions of the bus-bar portions to substantially one-quarter of the length of the bus-bar portions, of the plurality of finger portions, or at positions in the vicinity of the finger portions.

10. The solar cell according to claim 5,
wherein the width of the finger portions provided with the plating terminal portions or the width of the finger portions closest to the plating terminal portions is wider than the width of the other finger portions.

11. The solar cell according to claim 10,
wherein the width of the finger portions formed in the vicinity of the plating terminal portions becomes wider approaching the plating terminal portions.

12. The solar cell according to claim 1,
wherein a coating layer is formed over the entire region on the primary surface except for regions where the plating terminal portions are provided and a region where the plated electrode is formed.

13. The solar cell according to claim 2,
wherein a coating layer is formed over the entire region on the primary surface except for regions where the plating terminal portions are provided and a region where the plated electrode is formed.

14. The solar cell according to claim 3,
wherein a coating layer is formed over the entire region on the primary surface except for regions where the plating terminal portions are provided and a region where the plated electrode is formed.

15. The solar cell according to claim 4,
wherein a coating layer is formed over the entire region on the primary surface except for regions where the plating terminal portions are provided and a region where the plated electrode is formed.

16. The solar cell according to claim 12,
wherein the coating layer is circularly formed around the plating terminal portions on the primary surface, and
the plated electrode is formed around the circularly formed coating layer.

17. A method for manufacturing a solar cell comprising an electrode formation step of forming a plated electrode on a primary surface of a photoelectric conversion portion by electrolytic plating,
wherein, in the electrode formation step, the electrolytic plating is performed, on the primary surface, using positions spaced apart from regions functioning as wiring-material connecting portions of the plated electrode as plating terminal portions.

18. The method for manufacturing the solar cell according to claim 17,
wherein the electrode formation step includes a step of forming a transparent conductive layer on the primary surface,
a mask formation step of forming a mask on the transparent conductive layer, and
a step of forming the plated electrode using the electrolytic plating on the transparent conductive layer on which the mask is formed, and
in the mask formation step, the mask is formed that is patterned so as to have finger openings for exposing regions for forming the finger portions on the transparent conductive layer and bus-bar openings for exposing regions for forming bus-bar portions on the transparent conductive layer, and so as to have terminal openings formed to overlap the finger openings or the terminal openings formed adjacent to the finger openings.

19. The method for manufacturing the solar cell according to claim 18,
wherein, in the mask formation step, the mask is formed that is patterned so that the width of the finger openings overlapping the terminal openings or the width of the finger openings closest to the terminal openings is wider than the width of the other finger openings.

20. The method for manufacturing the solar cell according to claim 18,
wherein, in the mask formation step, the mask is formed that is patterned so that the width of the finger openings located in the vicinity of the terminal openings becomes wider approaching the terminal openings.
